(19) United States
(12) Patent Application Publication
(10) Pub. No.: US 2019/0078913 A1
(43) Pub. Date: Mar. 14, 2019

(54) ZERO-POWER SENSOR APPARATUS, METHOD, AND APPLICATIONS

(71) Applicant: CORNELL UNIVERSITY, Ithaca, NY (US)

(72) Inventors: Amit Lal, Ithaca, NY (US); Alyosha Molnar, Ithaca, NY (US)

(73) Assignee: CORNELL UNIVERSITY, Ithaca, NY (US)

(21) Appl. No.: 15/767,913

(22) PCT Filed: Oct. 13, 2016
(86) PCT No.: PCT/US2016/056826

§ 371 Date: Apr. 12, 2018

Related U.S. Application Data
(60) Provisional application No. 62/240,602, filed on Oct. 13, 2015.

(51) Int. Cl. G01D 21/02; H01L 41/113; H01H 59/00

(52) U.S. Cl. CPC G01D 21/02; H01H 59/0009; H01L 41/1132

(57) ABSTRACT

A zero power sensor node includes a sensor suite including two or more different types of zero power sensors, particularly including at least two of a zero power PZT-bimorph accelerometer, a zero power PZT-bimorph rotation sensor, a zero power PZT-bimorph magnetic sensor, a zero power PZT-bimorph gyroscope, and a zero power acoustic sensor, which may be a PZT-bimorph acoustic sensor or an resonant cavity, and a near zero power-consuming, multi gate electrostatic switch. The node output can send a wake-up signal to trigger a higher power consuming device.

### RELATED APPLICATION DATA

The instant application derives priority from U.S. Application No. 62/240,602 filed Oct. 13, 2015, the subject matter of which is herein incorporated by reference in its entirety.

### BACKGROUND

### 1. Field of the Invention

Embodiments of the invention are generally in the field of sensors; more particularly, zero power-consuming sensors and sensor assemblies including near-zero power-consuming electrostatic switches, which generate voltages and currents; and most particularly, PZT/bimorph zero power-consuming sensors and sensor assemblies including near-zero power-consuming electrostatic switches, methods, and applications including using the sensor assemblies to activate digital components.

### 2. Related Art

Wireless sensor nodes are usually battery or energy harvester powered. The wireless capability can be implemented using RF links, ultrasonic links, acoustic links, photonic x-ray links, etc. The operational time and reliability of a sensor wireless node is to a large part determined and/or limited by the longevity of the energy source(s) used to power the sensor nodes. In order to have sensor nodes operational for long periods of time, battery power consumption has to be minimized such that the battery can last as long as possible. The power consumed by the sensor segment of the sensor node is especially critical as the sensors have to be on all of the time. The inclusion of energy harvesters, if the harvested energy is greater than used, can greatly prolong the operational lifetime. However, in many real cases, the energy available to harvest is far lower than needed to run wireless sensor nodes continuously.

A further recognized problem pertains to signal stimulus discrimination. If a powered sensor is woken up too often due to false positive signal stimulation, battery power will be more readily consumed. Likewise, failure to detect a signal (false negative) will render the system unreliable. Thus the solution requires an intelligent sensor apparatus.

There exists a need to address these issues and problems, which need is met by the embodied invention. To that end, it would be advantageous and beneficial to provide a set of sensors that consume zero or near-zero power, but can wake-up an otherwise turned-off, powered sensor node. Once awoken, the powered sensors would presumably be capable of detecting signals at higher levels of fidelity, and transmit signals at a higher rate. Furthermore, discrimination is enhanced by sensing multiple signal stimuli simultaneous; e.g., motion/movement, acceleration, rotation, magnetic fluctuation, acoustic stimulus, and others. Such an intelligent sensor apparatus is enabled by the embodied invention.

### SUMMARY

An aspect of the invention is a zero power-consuming sensor suite made up of a plurality of zero power-consuming sensors that measure different signal stimuli. In an exemplary embodiment, the sensor suite includes a PZT-bimorph accelerometer, a PZT-bimorph rotation sensor, a PZT-bimorph magnetic sensor, and an acoustic sensor. The background and basis of the PZT-bimorph technology can be found in commonly assigned U. S. patent Application Publication US2016/0072041, the subject matter of which is incorporated herein by reference to the fullest extent permitted by all applicable patent Rules and laws. In this technology, a monolithic, bulk piezoelectric actuator includes a bulk piezoelectric substrate having a starting top surface and an opposing starting bottom surface and a at least two electrodes operatively disposed on the bulk piezoelectric substrate consisting of at least two discrete electrodes disposed on either/both of the starting top surface and the starting bottom surface and at least one electrode disposed on the respective other starting bottom surface or starting top surface. The embodied PZT-bimorph sensors are in the form of energy harvesters that extract energy from the environment and generate their own voltages, which are then typically amplified using electronic amplifiers. The fabrication process disclosed in the published '041 application enables many of the bimorph sensors to be fabricated in/on one PZT plate, further enabling integration of many of the sensors on one; single structure.

An exemplary zero power PZT-bimorph accelerometer includes a PZT-bimorph cantilever beam and a proof mass attached to one end thereof.

An exemplary non-resonant, zero power PZT-bimorph, passive gyroscope is realized using an array of accelerometers, which can measure centripetal force.

An exemplary zero power PZT-bimorph rotation sensor is made up of a plurality of PZT-bimorph accelerometers arrayed in a radial, spoke-like geometry. The embodied sensor

An exemplary zero power PZT-bimorph magnetic sensor is made by attaching a magnet to the bimorph. In an embodiment, a magneto-electric magnetometer comprising a magnetostrictive material can be integrated within the PZT substrates.

An exemplary zero power PZT-bimorph acoustic sensor implements a microphone with the bimorph having a z-cut in the center of the two bimorph electrodes leading to a z-displacement sensitivity. Alternatively, a flap(s) can be attached to the bimorph such that the net force on the flap(s) leads to bimorph motion. In order to measure acoustic signals with frequency selectivity, the spring and masses of the microphone bimorphs can be selected to correspond to specific resonance beams.

An exemplary zero power, non-PZT-bimorph acoustic sensor comprises a multi-resonant acoustic cavity that can filter incoming sound owing to the multiple resonances of the cavity. This embodiment of an acoustic sensor may be in the form of a box that can be made resonant at desired frequencies and in which other sensors such as those referred to immediately above can be packaged. Different combination sensor plates may be placed at select positions along the box to form resonant Helmholtz cavities. A series of the resonators can be formed to form multiple resonances. An output port of the acoustic resonator can have a piezoelectric bimorph microphone element to measure the pressure of the filtered signal.

An aspect of the invention is a sensor assembly including a zero power sensor suite as disclosed herein whose output is coupled to a near-zero power-consuming electrostatic switch. Near-zero power-consuming electrostatic switches are described in K. Amponsah, N. Yoshimizu, S. Ardanuc, and A. Lal., IEEE NEMS 2010, pp. 985-988, incorporated herein in its entirety to the fullest extent permitted by all applicable patent Rules and laws. The voltage and the energy from the sensor suite can be used to trigger the electrostatic switch for a given frequency range. An electrostatic switch does not consume any DC power as the gaps between electrodes are insulating air or vacuum gaps. Hence, a DC bias applied to the electrodes of an electrostatic switch can be used to bias the switch to a tunable voltage of triggering the switch. The DC bias can be formed from a series of electrodes that prebias the switch. Each of the electrodes, with designable area, and gap, can be designed to have a weight corresponding to the binary weight of a binary number. The binary number can be written into a SRAM memory cell that is connected to each of the electrodes. By nature of the SRAM cell, the power consumed to retain a digital state is minimal, only determined by the leakage current of the off transistors. The weight on the bits can be programmed such that the switch is turned on for a desired threshold voltage on the sensor. In the embodied invention, the switch electrodes and contacts are deposited with a secondary layer that has better stiction properties, such as graphene to overcome stiction at the switch contact point. Because the signals to be detected are very small, the NEMS switch must be almost closed even before the RF or sensor signal is present. Switch control may be enabled by mixed signal calibration, similar to that used to calibrate RF oscillators. Primary control is through a set of digitally controlled electrodes (driven to either 0 or 1 V) binary weighted by area. In conjunction with mixed signal control, analog feedback may be used to maintain the state of the NEMS switches. As a NEMS switch approaches a closed state, there will be a small tunneling current through the contact even before it is fully closed. Integrating this current onto a large capacitor with a small amount of leakage can provide a feedback signal for controlling the NEMS switch and maintaining it at a very nearly closed state.

Switch activation can be used to wake-up or further activate other digital components.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTIONS OF FIGURES

FIG. 1 (left) schematically (center) pictorially and (right) schematically shows a zero power PZT-bimorph accelerometer sensor, according to an illustrative aspect of the invention;

FIG. 2 (left) schematically shows a zero power PZT-bimorph non-resonant passive gyroscope; FIG. 2 (right) schematically shows a comparator circuit such that voltage is generated only when there is a net rotation of the sensor.

FIG. 3 (left) schematically and (right) pictorially shows a zero power PZT-bimorph rotation sensor, according to an illustrative aspect of the invention;

FIG. 4 (left) schematically and (right) pictorially shows a zero power PZT-bimorph magnetic sensor, according to an illustrative aspect of the invention;

FIG. 5 schematically (left) in perspective and (right) top view shows a zero power PZT-bimorph magnetostrictive sensor, according to an illustrative aspect of the invention;

FIG. 6 pictorially shows a zero power PZT-bimorph acoustic sensor, according to an illustrative aspect of the invention;

FIGS. 7A and 7B pictorially show a non-PZT multi-resonant acoustic cavity in the form of a box; FIG. 7C graphically and pictorially shows resonant modes formed of the case to create a filter, according to an illustrative aspect of the invention;

FIG. 8 pictorially shows a single plate fabricated to contain a sensor suite including an accelerometer sensor, a magnetic sensor, a gyroscope, and a rotation sensor, according to an illustrative aspect of the invention;

FIGS. 9A, 9B, and 9C show different views of a near-zero power-consuming electrostatic switch, according to an illustrative aspect of the invention;

FIG. 10 schematically shows a graphene/silicon/copper switch, according to an illustrative aspect of the invention;

FIG. 11 schematically shows the switch circuit, according to an illustrative aspect of the invention;

FIG. 12 schematically shows the switch circuit, according to an illustrative aspect of the invention;

FIG. 13 schematically shows a zero power multi sensor suite with weighted gate switches, according to an illustrative aspect of the invention.

FIG. 14A schematically shows the fabrication process flow for the switch; FIG. 14B is a SEM image of the NEMS switch; FIG. 14C shows the switching hysteresis plot of the switch.

### DETAILED DESCRIPTION OF EXEMPLARY, NON-LIMITING EMBODIMENTS OF THE INVENTION

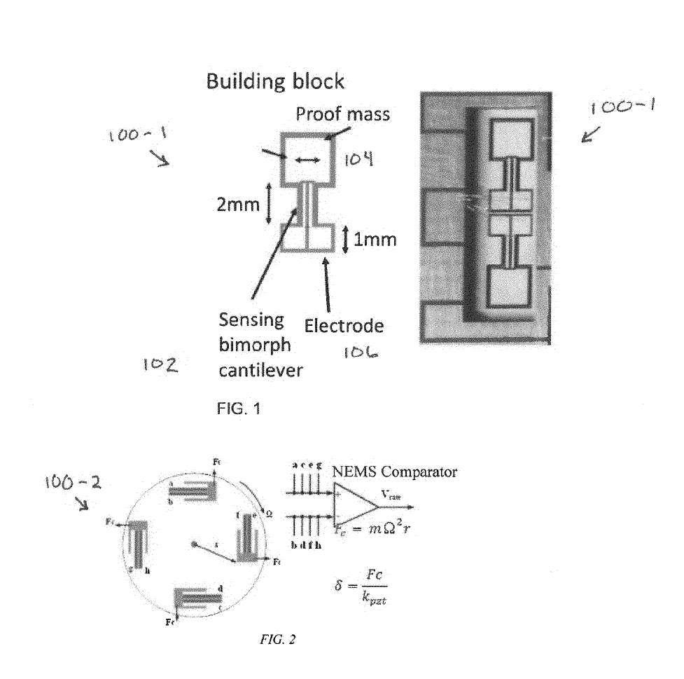

FIG. 1 illustrates an exemplary zero power-consuming PZT-bimorph accelerometer 100-1. The accelerometer comprises a PZT-bimorph cantilever beam 102 and a proof mass 104 attached to an end of the beam; electrode structure 106 is also shown. The resonance frequency of this structure can be tuned by selecting different dimensions for the spring (cantilever) and mass sections. The accelerometer in the right side figure can have resonances from 10 to 5 kHz and can be oriented in one PZT plate for two-axis sensitivity. It produces ˜6-60 mV/g of acceleration, capable of generating 6-60 μV/mg to detect automobile motion at standoff distances of >10 musing NEMS switch triggers. When shaken in the sensitive direction, the two electrodes will generate the highest voltage difference between them, as compared to when shaken in non-sensitive directions such as out-of-plane.

FIG. 2 (left) schematically shows a zero power PZT-bimorph non-resonant passive gyroscope 100-2 realized using a quadrature array of accelerometers. FIG. 2 (right) schematically shows a comparator circuit that generates voltage only when there is a net rotation of the sensor. Rotation signal maybe useful to differentiate between an adversary trying to remove and carry a sensor node in which case rotation signal will be inevitable.

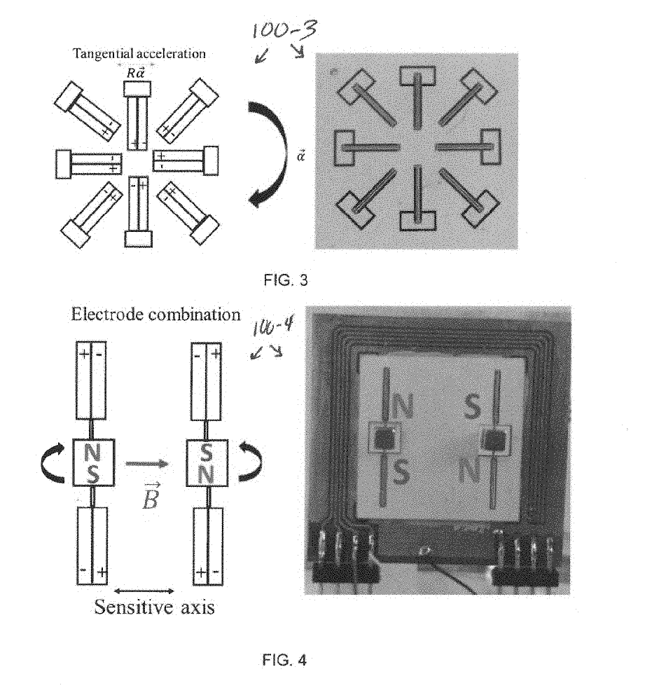

FIG. 3 (left) schematically and (right) pictorially shows a zero power PZT-bimorph rotation sensor 100-3. To sense rotation, a plurality of accelerometers are arrayed in a circular geometry, where each accelerometer senses angular acceleration when under rotation. This angular acceleration is

$${a}_{r} = \frac{{v}^{2}}{R} = {ω}^{2} R$$

where ω is the angular rotation rate.

Under rotation, each of the bimorphs bends out creating a voltage across each of the beams. By choosing the electrodes shown as a plus electrode, and minus electrode respectively together, the net voltage across the bimorphs is zero for net accelerations, but non-zero for rotation. This sensor output is proportional to the square of the rotation rate, not the rotation itself, as is the case in a gyroscope.

FIG. 4 (left) schematically and (right) pictorially shows a zero power PZT-bimorph magnetic sensor 100-4. In order to sense magnetic fields, a magnet is attached to the bimorph. Any external magnetic field leads to a net force on the bimorph producing a voltage signal. The bimorph is also an accelerometer, and in order to differentiate acceleration from magnetic fields, one can configure the electrodes in the polarity shown to cancel out any accelerometer signal from the magnetic sensor. The output of the magnetic sensor can be written as Vₘ=c₁*B+c₂*a where B and a are magnetic field and accelerations. The output of the acceleration can be taken out of Vᵢₙ to give mainly a magnetic field signal.

FIG. 5 schematically (left) in perspective and (right) top view shows a zero power PZT-bimorph magnetostrictive sensor (magnetometer) 100-5. The magnetic fields generated from driving traffic is one of the key signatures to trigger a sensor node to a high power consumption, high accuracy mode of sensing. Furthermore, with the easy availability of flying UAVs, the magnetic signature may be more important than acceleration and microphonic measurements to detect intruders. The magnetic fields from driving cars and trucks are in the range of milliGauss at distances of 15 feet to a few 100s of milliGauss at a 1-foot distance. This range of magnetic flux density corresponds to 1-100 Oersteds of magnetic field. Given that the sensor has to work at zero power, a magneto-electric magnetometer can be integrated within the PZT substrates. Magneto-electric sensors consist of a magnetostrictive material that strains due to a magnetic field, and that strain is applied to a piezoelectric actuator to generate a voltage. This realizes a direct magnetic field to electric field transducer. Macro scale maanetoelectric magnetic field sensors with sensitivities of 1-20 mV/Oe and equivalent noise of 1-10 pT/root-Hz have been reported. These sensors would provide sufficient SNR to measure the fields presented by driving traffic. Magnetostrictive materials that can be integrated within the PZT bimorphs include nickel, and an advanced material called Terfenol-D (http://www.etrema-usa.com/documents/Terfenocan). Nickel can be electroplated into trenches inside bimorphs, and Terfenol-D bars can be deposited into the bimorphs. Nickel has a lower saturation magnetization and hence is easier to fabricate, while Terfenol-D has a much larger operating range, but is harder to fabricate. The magnetostrictive coefficients are 2-5 ppm strain/Oe, and this can be applied to the PZT bimorph. PZT is known to have high electromechanical coupling coefficients (5-15%) and PZT-4 plates have large piezoelectric voltage constants g₃₁ (11*10⁻³ Vm/N). We have experimentally measured strain sensitivities ˜7.5 μV/ppm for our lateral bimorph devices. Therefore, we expect a composite lateral bimorph with cross-section shown above to have sensitivities to magnetic fields ˜37.5 μV/Oe. Given an average noise voltage of 100-200 uV across typical PZT bimorphs, we anticipate resolution of 4-5 Oe.

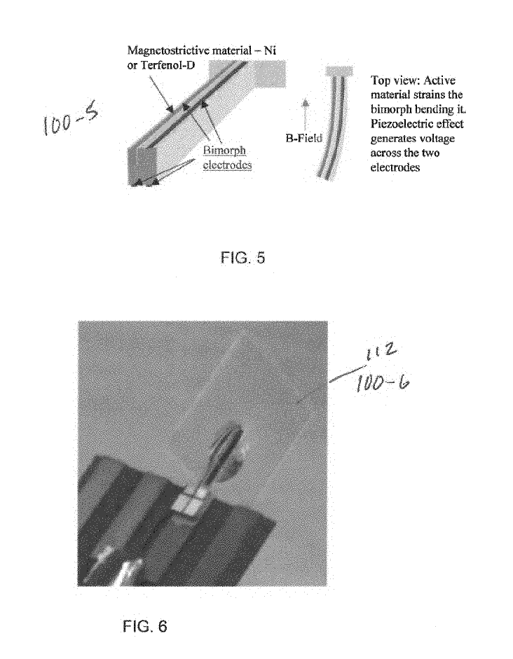

FIG. 6 pictorially shows a zero power PZT-bimorph acoustic sensor 100-6. In order to sense an acoustic field, a microphone can also be implemented using the bimorphs. A bimorph with a z-cut in the center of the two bimorph electrodes leads to a z-displacement sensitivity. An acoustic pressure wave would apply a net force across the plate producing a voltage. Alternatively, flaps 112 can be attached to the bimorph such the net force leads to bimorph motion. Accelerations can be separated out by using accelerometer bimorphs to subtract out the acceleration from the microphone bimorph.

In many signature events to be detected, the acoustic output is in one or more specific frequency ranges. Hence, it is often desirable to measure the acoustic signals with frequency selectivity. This can be achieved by picking the spring and masses of the microphone bimorphs to correspond to specific resonance beams.

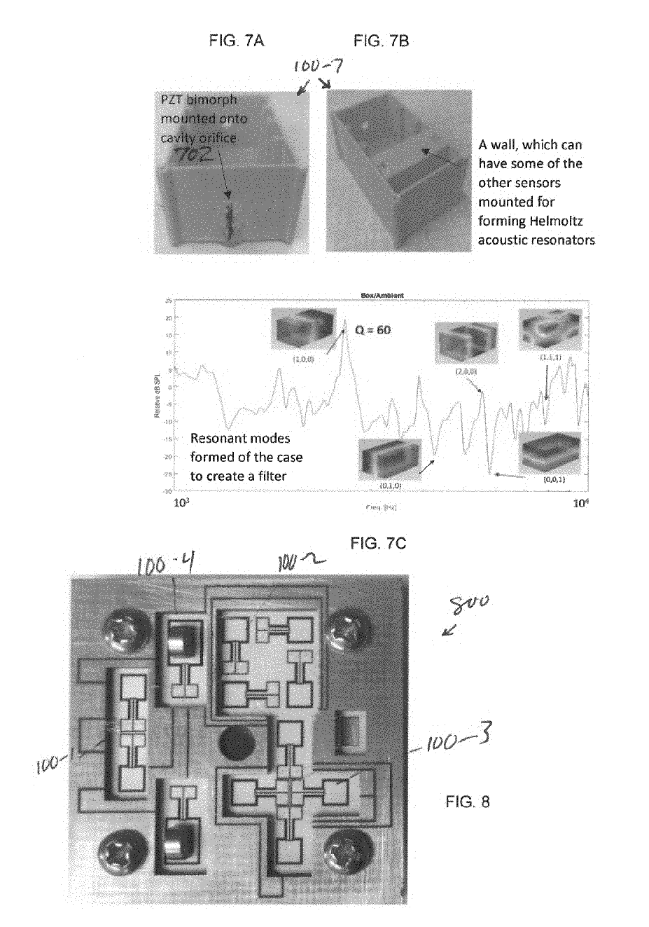

Another approach is to create a multi-resonant acoustic cavity that can filter incoming sound owing to the multiple resonances of the cavity. FIGS. 7A and 7B pictorially show a non-PZT multi-resonant acoustic cavity 100-7 in the form of a box; FIG. 7C graphically and pictorially shows resonant modes formed of the case to create a filter. A box geometry acoustic cavity, on the order of 5×5×5 cm, is advantageous in that the other sensors can be packaged therein. Smaller cavities can also be formed if the sensors can be also packaged on smaller susbtrates. By careful co-design, the box can be designed to house the other sensors, and be resonant at desired frequencies. For example, the other sensor plates can be placed at select positions along the box to form resonant Helmholtz cavities. A series of the resonators can be formed to form multiple resonances. The output port of the acoustic resonator will have a PB microphone element 702 to measure the filtered signal.

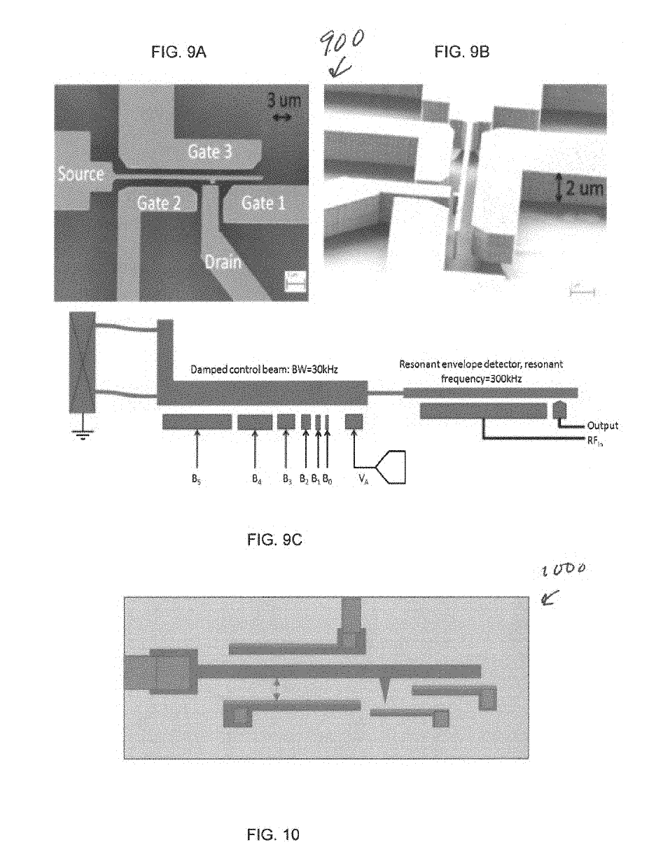

FIG. 8 pictorially shows a single plate 800 fabricated to contain a sensor suite including an accelerometer sensor 100-1, a magnetic sensor 100-4, a gyroscope 100-2, and a rotation sensor 100-3. The wiring from each of the plus and minus electrodes can be connected off the sensor by wirebonds, or a two level interconnect process using an intermediate electrical isolation layer.

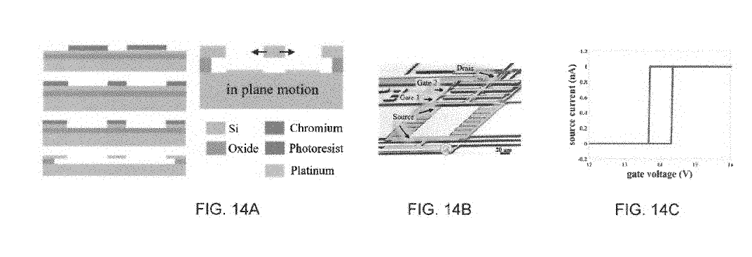

Each of the sensors described above generates a voltage across a capacitor, which represents stored energy. The voltage and the energy can be used to trigger an electrostatic switch for a given frequency range. FIGS. 9A, 9B, and 9C show different views of a near-zero power-consuming electrostatic switch 900. FIG. 14A schematically shows the fabrication process flow for the switch; FIG. 14B is a SEM image of the NEMS switch; FIG. 14C shows the switching hysteresis plot of the switch. By using electrostatic micro or nano mechanical switches, the switch power consumption can be near zero, determined only by the leakage currents across vacuum or air gaps, and across insulating thin films. By near-zero power, we imply power that is much smaller or comparable to the leakage power of the battery being used to power a sensor node. In this way, the lifetime of the sensor that never triggers will be comparable to the lifetime of the battery under no load. In order to make the lifetime of the sensor very long, longer than that of a battery under no load, energy harvesters can be used to charge discharging batteries. We have developed micro fabricated switches that are actuated by electrostatic forces due to voltages on the gates. An electrostatic switch does not consume any DC power as the gaps between electrodes are insulating air or vacuum gaps. Hence, a DC bias applied to the electrodes of an electrostatic switch can be used to bias the switch to a tunable voltage of triggering the switch. The DC bias can be formed from a series of electrodes that prebias the switch. Each of the electrodes, with designable area, and gap, can be designed to have a weight corresponding to binary weight of a binary number as illustrated in FIG. 9C. The binary number can be written into a SRAM memory cell that is connected to each of the electrodes. The weight on the bits can be programmed such that the switch is turned on for a desired threshold voltage on the sensor.

A risk factor for the NEMS nanoswitches is their tendency to stay closed after contact due to Van der Waal forces, microwelding, or other stiction forces. FIG. 10 schematically shows a multilayer graphene/silicon/copper switch 1000, showing deposition of graphene on the electrodes and contacts. Graphene and or carbon films can potentially overcome stiction at the switch contact point. Previous attempts at an all graphene switch confirm low surface energy, but also tearing of the membranes suspected due to graphene dislocations. We propose to place graphene solidly on a silicon/copper surface. Graphene is also hydrophobic and the weak interactions between stacked graphene sheets has been demonstrated for high reliability mechanical systems. Graphene coating also has potential to compensate temperature dependent silicon softening and gap changes. In order to reduce the temperature sensitivity of the spring constants and the gaps, we use graphene/copper/silicon thermal bimorphs integrated within the switch electrodes to adjust the gaps with temperature. Due to the negative thermal expansion coefficient of graphene, the graphene can be used to cancel the bimorph effects of the copper and silicon. As seen in FIG. 10, copper thin films are deposited on the sides of the electrodes by a combination of nanoscale shadow deposition and lithography and use thin oxide or nitride films as diffusion barriers for copper or other metal diffusion into the silicon beam. The copper beams have a TCE of 16.6 ppm/K, compared to 2.6 ppm/K for silicon enabling bimorph action. As the temperature is increased, the Young's modulus of silicon will decrease, causing a decrease in the actuation voltage of the switches with reduced spring constant of the beam. In the case of pull-in-voltage, the pull-in voltage is proportional to the square root of the spring constant, and will decrease with temperature increase. For non-pull in actuation of the switch, the displacement is proportional to the force divided by the spring constant, and since the electrostatic force is proportional to the square of the voltage, the displacement to switching will occur at a lower voltage for a softened spring for a fixed electrode gap. In order to compensate for the reduction in spring constant, we can increase the gaps, making the gaps a function of the temperature, to compensate for the softening related actuation voltage decrease. This can be done by including a thermal bimorph for the contact electrodes instead of a fixed electrode as is traditionally done in electrostatic switches. Each of the electrodes is a beam element such that it moves away from the silicon beam as temperature is varied. The bimorph can be formed by forming different layers of different materials, notably graphene, metal, and silicon.

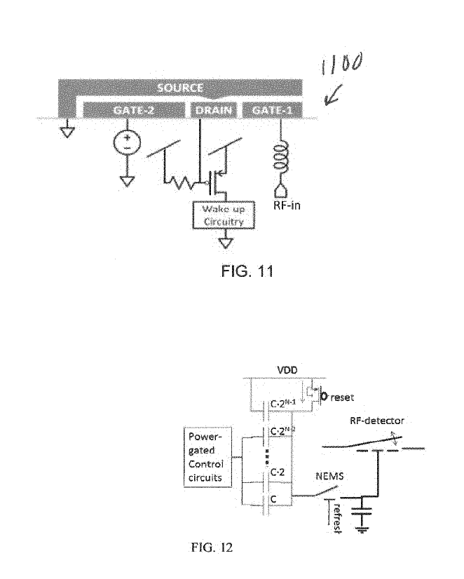

A key approach to detecting low power signals while consuming nearly zero power is the rectifying, strongly nonlinear behavior of the NEMS switches. Because the signals to be detected are very small, the NEMS switch must be almost closed even before the RF signal is present. FIG. 11 schematically shows the switch circuit 1100. Quantitatively, the amount of displacement an RF signal will generate is

$$Δ g = {k}_{spring}^{- 1} ϵ \frac{{A}_{RF\_el} {V}_{RF}^{2}}{4 {( {g}_{RF} )}^{2}}$$

where V_{RF} is the RF voltage on the electrode, k_{spring} is the spring constant of the switch, A_{RF}_{_}ₑₗ is area of the RF electrode, g_{RF} is the gap of the RF electrode, and Δg<<g_{RF} is the gap between the source and drain that needs to be closed. For example, if k_{spring}=20 mN/m, A_{RF}_{_}ₑₗ=256 μm², g_{RF}=15 nm, and V_{RF}=3 mV, then Δg=5 nm. This scale of gap is also reasonable from a noise immunity standpoint. Brownian motion will generate noise in the displacement of the NEMS switch by σ_{g}²=k_{B}T/k_{spring}. For k_{spring}=20 mN/m, this corresponds (at room temperature) to σ_{g}=0.44 nm. By the same argument as above, a false positive rate of less than once per hour requires a noise margin of about 6, or a gap of about 2.7 nm; thus a target gap of 5 nm provides margin, as long as it is achieved with ˜1 nm precision. This level of precision across variations in manufacturing, temperature, battery voltage, interference, etc. requires adaptive control and calibration. The control approach will be partially shared across all of the NEMS switches to account for common sources of variation.

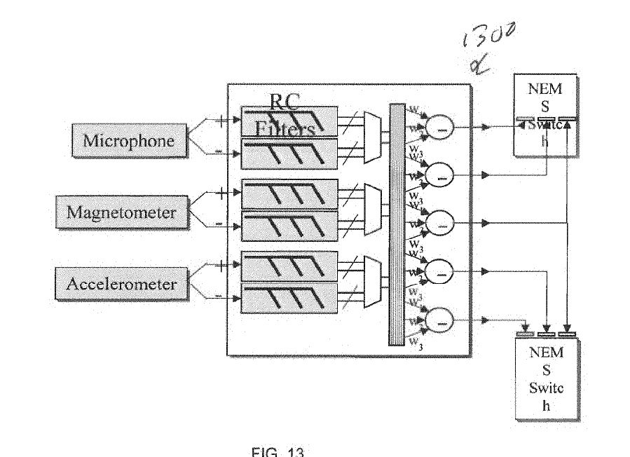

The primary form of control we propose here will be a mixed signal calibration, similar to those used to calibrate RF oscillators. Primary control is through a set of digitally controlled electrodes (driven to either 0 or 1 V), binary weighted by area. Assuming the design avoids pull-in, the starting gap, gₒ, must be more than 3× the bias in displacement induced by the control. This displacement will be roughly

$$Δ {g}_{bias} = {k}_{spring}^{- 1} ϵ \frac{{A}_{BIAS} {V}_{DD}^{2}}{2 {( {g}_{0} - Δ {g}_{bias} )}^{2}}$$

where A_{BIAS} is the combined area of the digital electrodes in a 1V (vs 0V) state, and so is controllable. It can be shown that to control Δg to ˜1 nm precision, with the same spring constant as above, gₒ=700 nm, and Δg_{bias}=200 nm, then A_{BIAS}=110 μm² and a 1 nm change in Δg_{bias} corresponds to a change of about 0.5 μm² in A_{bias}. Including a factor of 2 margin in maximum control strength, this corresponds to at least 9 bits of control. Although some of these 9 bits could be shared among the different NEMS switches, variation between switches means that at least some of the control bits would need to be independent for each switch, requiring many wires for control. Therefore, we propose a mixed-mode approach wherein the 6 MSBs (most significant bits) are digital, and shared across the NEMS switches. The remaining control is handled by independent DACs, one for each switch. FIG. 12 schematically shows an exemplary DAC, with signal held through a NEMS sample and hold.

Secondary mixed signal control is provided by an additional 6-8 bits of control applied to each switch through a set of digital-to-analog converters on the CMOS chip. Because force, and so displacement, depend on the square of this analog voltage, the MSB of each DAC will always be exerted (its charge is potentially needed to be refreshed periodically) to keep the voltage in the upper half of its range. Because they consume essentially zero power while in the holding state for extended periods of time, charge-redistribution DACs are the preferred circuits for this situation, consuming only the leakage power of the (˜8) digital memory cells to maintain state, and only requiring the energy to switch the relevant capacitors when updating, providing a very low power solution. There may be some leakage on the main, hold capacitance, from the reverse biased diodes inherent to MOSFET reset switches. To reduce this, the DACs can be combined with off-chip hold capacitors and NEMS switches (operated in binary, pull-in mode) as shown in FIG. 11 to hold the voltages with very low leakage.

Ideally, the state of the NEMS switches would be maintained through continuous feedback, rather than discrete calibration events. However, most forms of feedback require active analog circuitry. However, as a NEMS switch approaches a closed state, there will be a small tunneling current through the contact even before it is fully closed. Integrating this current onto a large capacitor with a small amount of leakage could provide a feedback signal for controlling the NEMS switch and maintaining it at a very nearly closed state. Such a loop will act, roughly, as a high-pass filter, suppressing slow changing perturbations. Since it is very difficult to design feedback loops that are simultaneously high dynamic range, low power and stable, any analog feedback will be in conjunction with the above mixed signal controls, providing increased tolerance to drift and leakage, but likely still requiring periodic refresh events to account for larger environmental excursions.

FIG. 13 schematically shows a zero power multi sensor suite 1300 with weighted gate switches, according to an illustrative aspect of the invention.

What is claimed is:

1. A zero-power sensor suite, comprising:
a zero-power PZT-bimorph magnetic sensor;
a zero-power PZT-bimorph accelerometer; and
a zero-power PZT-bimorph rotation sensor, wherein all of the sensors are disposed on a single plate.

2. The zero-power sensor suite of claim 1, further comprising a zero-power PZT-bimorph acoustic sensor.

3. The zero-power sensor suite of claim 1, further comprising a zero-power PZT-bimorph gyroscope sensor.

4. The zero-power sensor suite of claim 1, wherein the zero-power PZT-bimorph accelerometer comprises a bimorph cantilever and a proof mass attached to an end of the bimorph cantilever.

5. The zero-power sensor suite of claim 1, wherein the zero-power PZT-bimorph accelerometer is characterized by a resonance from 10 Hz to 5 kHz.

6. The zero-power sensor suite of claim 1, wherein the zero-power PZT-bimorph rotation sensor comprises a plurality of the zero-power PZT-bimorph accelerometers arranged in a radial, hub/spoke geometry.

7. The zero-power sensor suite of claim 1, wherein the zero-power PZT-bimorph rotation sensor has an output dependent on the square of the angular rotation rate.

8. The zero-power sensor suite of claim 1, wherein the zero-power PZT-bimorph magnetic sensor comprises a magnet attached to a PZT bimorph.

9. The zero-power sensor suite of claim 2, wherein the zero-power PZT-bimorph acoustic sensor comprises a lateral PZT-bimorph and a flap attached to the bimorph.

10. The zero-power sensor suite of claim 2, wherein the zero-power PZT-bimorph acoustic sensor is frequency selective.

11. A zero-power sensor suite, comprising:
multi-resonant acoustic cavity structure; and
at least one of a zero-power PZT-bimorph magnetic sensor, a zero-power PZT-bimorph accelerometer, a zero-power PZT-bimorph gyroscope, and a zero-power PZT-bimorph rotation sensor disposed in the multi-resonant acoustic cavity structure.

12. A zero-power sensor node, comprising:
the zero-power sensor suite of claim 11, wherein the sensor suite is operatively coupled to a near-zero power-consuming, multi-gate MEMS/NEMS switch, further wherein the switch includes electrodes having a weight corresponding to a programmable binary weight of a binary number corresponding to a desired threshold voltage, further wherein the electrodes and contacts of the switch have a graphene coating.

13. The zero-power sensor node of claim 12, wherein the switch electrodes have a multilayer carbon/copper/silicon thermal bimorph integrated within to adjust the gaps with temperature.

14. The zero-power sensor node of claim 12, wherein the switch electrodes have a multilayer graphene/copper/silicon thermal bimorph integrated within to adjust the gaps with temperature.

15. A zero-power sensor node, comprising:
the zero-power sensor suite of claim 1, wherein the sensor suite is operatively coupled to a near-zero power-consuming, multi-gate MEMS/NEMS switch, further wherein the switch includes electrodes having a weight corresponding to a programmable binary weight of a binary number corresponding to a desired threshold voltage, further wherein the electrodes and contacts of the switch have a graphene coating.
